(19) United States
(12) Patent Application Publication
(10) Pub. No.: US 2011/0226512 A1
(43) Pub. Date: Sep. 22, 2011

(54) Heatsink Device Having A Rapid Heatsink Effect

(76) Inventor: Yao-Tsung Kao, Tainan City (TW)

(21) Appl. No.: 12/728,401

(22) Filed: Mar. 22, 2010

(51) Int. Cl. H05K 7/20

(52) U.S. Cl. 174/252

(57) ABSTRACT

A heatsink device includes a heatsink body and at least one heatsink member. The heatsink member is made of a metallic material different from that of the heatsink body. The heatsink member is combined with the heatsink body by a friction welding machine without needing any solder, conducting paste, adhesive or bonding agent, so that the heatsink body is directly combined with the heatsink member without an obstruction located between the heatsink body and the heatsink member so as to enhance the heatsink effect of the heatsink device.

### BACKGROUND OF THE INVENTION

1. Field of the Invention

The present invention relates to a heatsink device and, more particularly, to a heatsink device for an electronic appliance, such as the circuit board of a computer and the like.

2. Description of the Related Art

A conventional heatsink device in accordance with the prior art shown in FIG. 5 comprises a heatsink body 1 and a cooling fan 12 mounted on the top of the heatsink body 1. The heatsink body 1 is made of an aluminum material and is formed by an aluminum extruding process. The heatsink body 1 is combined with a circuit board (not shown). The heatsink body 1 has an upper end provided with a plurality of heatsink fins 11 and a plurality of heatsink channels 110 defined between the heatsink fins 11. However, the circuit board produces a great deal of heat so that the cooling fan 12 cannot carry away the heat exactly.

Another conventional heatsink device in accordance with the prior art shown in FIG. 6 comprises a heatsink body 2, a cooling fan 22 mounted on the top of the heatsink body 2, and a copper plate 20 mounted on the bottom of the heatsink body 2 by a conducting paste 21. Thus, the copper plate 20 can carry away the heat quickly to enhance the heatsink effect. However, the conducting paste 21 is located between the copper plate 20 and the heatsink body 2 so that the copper plate 20 cannot directly transmit the heat to the heatsink body 2, thereby decreasing the heatsink effect.

### BRIEF SUMMARY OF THE INVENTION

In accordance with the present invention, there is provided a heatsink device, comprising a heatsink body, a cooling fan mounted on a top of the heatsink body, and at least one heatsink member combined with the heatsink body. The heatsink body is combined with a circuit board. The heatsink body has an upper end provided with a plurality of heatsink fins and a plurality of heatsink channels defined between the heatsink fins. The heatsink body is made of a metallic material. The heatsink member is made of a metallic material different from that of the heatsink body. The heatsink member is combined with the heatsink body in a friction welding manner without needing any solder.

Preferably, the heatsink member is made of a copper material.

Preferably, the heatsink member has a periphery provided with a plurality of irregular or rough surfaces.

Preferably, the heatsink member is an elongate copper rod or a flat plate.

The primary objective of the present invention is to provide a heatsink device having a rapid heatsink effect.

According to the primary objective of the present invention, the heatsink body and the heatsink member are combined together by a friction welding machine without needing any solder, conducting paste, adhesive or bonding agent, so that the heatsink body is directly combined with the heatsink member without an obstruction located between the heatsink body and the heatsink member so as to enhance the heatsink effect of the heatsink device.

According to another objective of the present invention, the heatsink member is attached to and combined with the heatsink body at a high temperature so that the heatsink body and the heatsink member are combined solidly and stably without incurring a detachment.

According to a further objective of the present invention, the heatsink device has a better heatsink effect so as to enhance the lifetime of the electronic appliance.

According to a further objective of the present invention, the heatsink member has a periphery provided with a plurality of irregular or rough surfaces to increase the surface friction between the heatsink member and the heatsink body and to increase the surface area of the heatsink member so as to enhance the heatsink effect of the heatsink device.

According to a further objective of the present invention, the heatsink member is attached to and combined with the heatsink body by a friction welding machine so that the heatsink body and the heatsink member are combined together easily and quickly.

Further benefits and advantages of the present invention will become apparent after a careful reading of the detailed description with appropriate reference to the accompanying drawings.

### BRIEF DESCRIPTION OF THE SEVERAL VIEWS OF THE DRAWING(S)

FIG. 1 is a partially exploded perspective view of a heatsink device in accordance with the preferred embodiment of the present invention.

FIG. 2 is a side cross-sectional assembly view of the heatsink device as shown in FIG. 1.

FIG. 3 is a perspective view of a heatsink member of the heatsink device in accordance with another preferred embodiment of the present invention.

FIG. 4 is a partially exploded perspective view of a heatsink device in accordance with another preferred embodiment of the present invention.

FIG. 5 is a perspective view of a conventional heatsink device in accordance with the prior art.

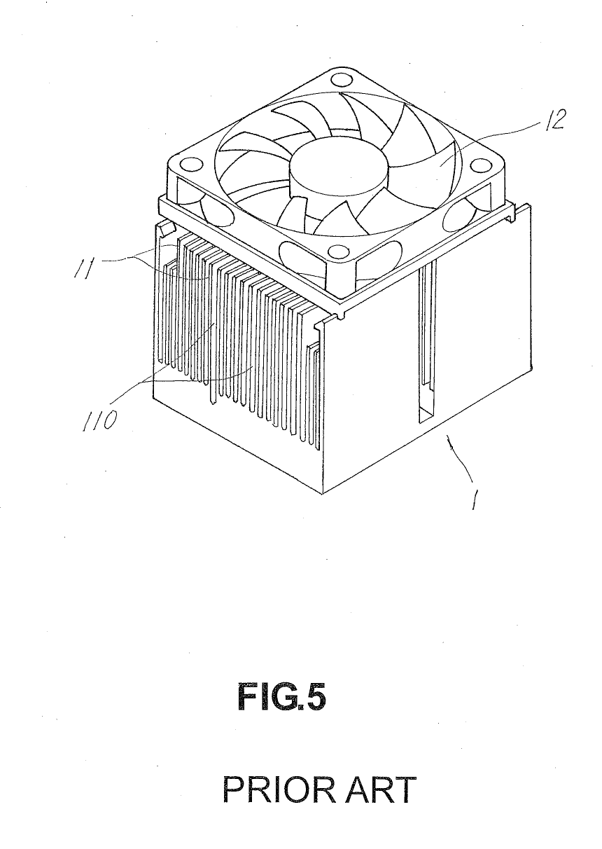

FIG. 6 is an exploded perspective view of another conventional heatsink device in accordance with the prior art.

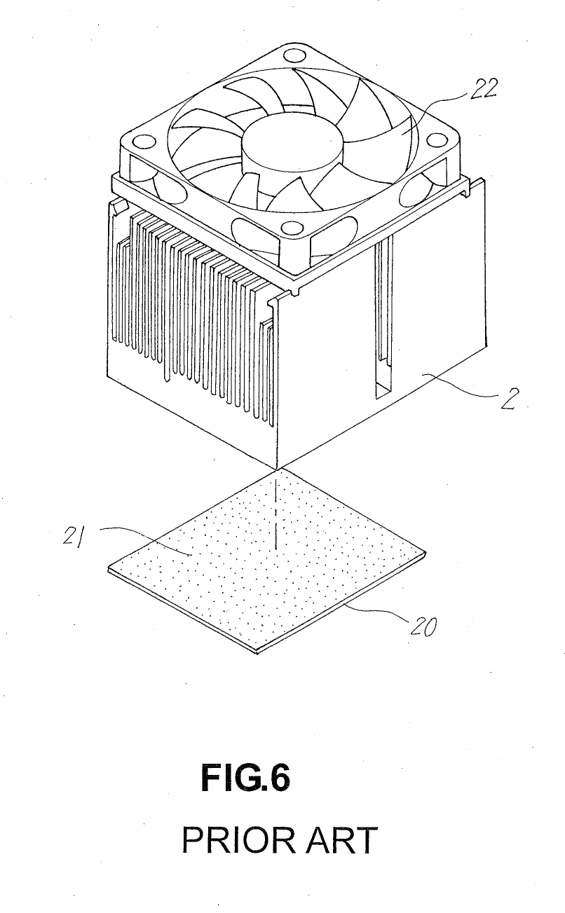

### DETAILED DESCRIPTION OF THE INVENTION

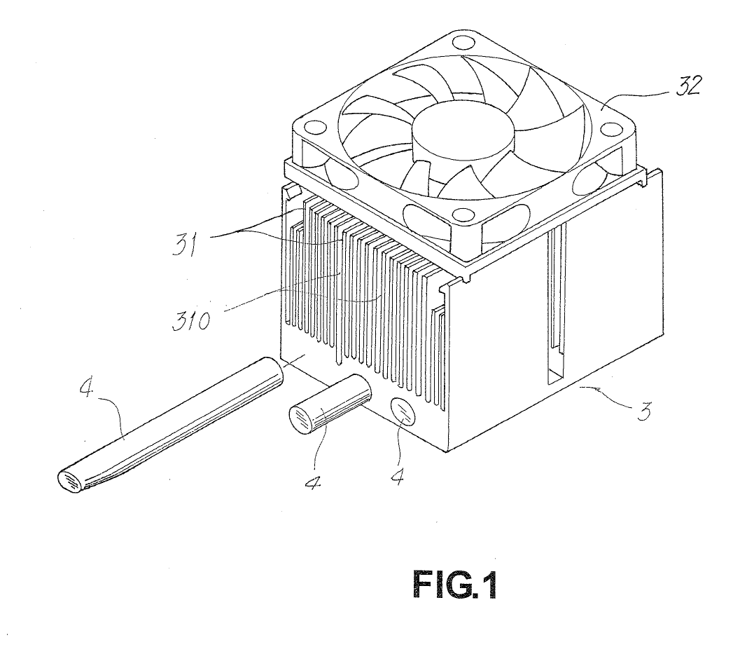

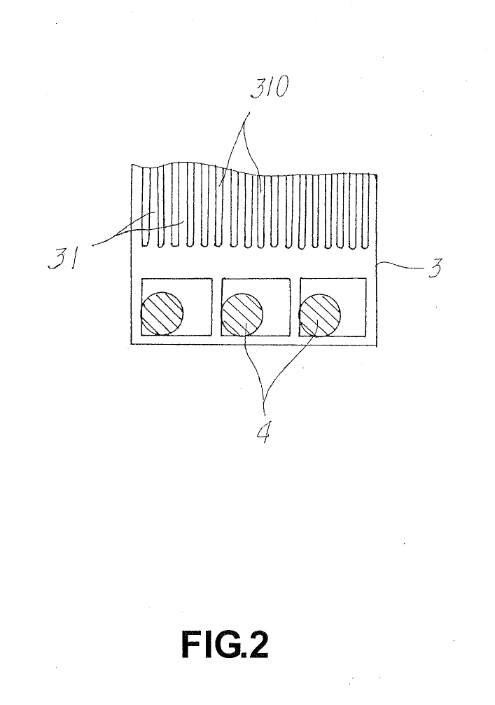

Referring to the drawings and initially to FIGS. 1 and 2, a heatsink device in accordance with the preferred embodiment of the present invention comprises a heatsink body 3, a cooling fan 32 mounted on a top of the heatsink body 3, and at least one heatsink member 4 combined with the heatsink body 3.

The heatsink body 3 is made of a metallic material, such as an aluminum material, and is formed by an aluminum extruding process. The heatsink body 3 is combined with a circuit board (not shown). The heatsink body 3 has an upper end provided with a plurality of heatsink fins 31 and a plurality of heatsink channels 310 defined between the heatsink fins 31.

The heatsink member 4 is made of a metallic material different from that of the heatsink body 3. Preferably, the heatsink member 4 is made of a copper material. In the preferred embodiment of the present invention, the heatsink member 4 is an elongate copper rod. The heatsink member 4 is combined with the heatsink body 3 in a friction welding manner without needing any solder. In the preferred embodiment of the present invention, the heatsink member 4 is combined with the heatsink body 3 by a friction welding machine (not shown).

In fabrication, the heatsink body 3 and the heatsink member 4 are positioned respectively. Then, the heatsink member 4 is driven by the friction welding machine to rotate relative to the heatsink body 3 at a high rotation speed. In such a manner, when the heatsink member 4 contacts the heatsink body 3, a high temperature is produced at the interface of the heatsink body 3 and the heatsink member 4 due to friction during the rotation process of the heatsink member 4 so as to weld the interface of the heatsink body 3 and the heatsink member 4 so that the heatsink body 3 and the heatsink member 4 are combined integrally. Thus, the heatsink body 3 and the heatsink member 4 are combined solidly and stably without incurring a detachment. In addition, the heatsink body 3 and the heatsink member 4 are combined together without needing any solder, conducting paste, adhesive or bonding agent, thereby greatly decreasing the cost of fabrication. In addition, the heatsink body 3 is directly combined with the heatsink member 4 to enhance the heatsink effect of the heatsink device.

As shown in FIGS. 1 and 2, the heatsink body 3 is made to have a hollow inside during the aluminum extruding process. In such a manner, when the heatsink member 4 contacts a first side of the heatsink body 3, a high temperature is produced at the first side of the heatsink body 3 due to friction during the rotation process of the heatsink member 4 so as to weld the first side of the heatsink body 3 so that the heatsink member 4 is extended through the first side of the heatsink body 3 into the heatsink body 3. Then, when the heatsink member 4 contacts a second side of the heatsink body 3, a high temperature is produced at the second side of the heatsink body 3 due to friction during the rotation process of the heatsink member 4 so as to weld the second side of the heatsink body 3 so that the heatsink member 4 is extended through the second side of the heatsink body 3. Thus, the heatsink member 4 is extended into and fixed in the heatsink body 3 between the first side and the second side of the heatsink body 3 so that the heatsink body 3 and the heatsink member 4 are combined integrally.

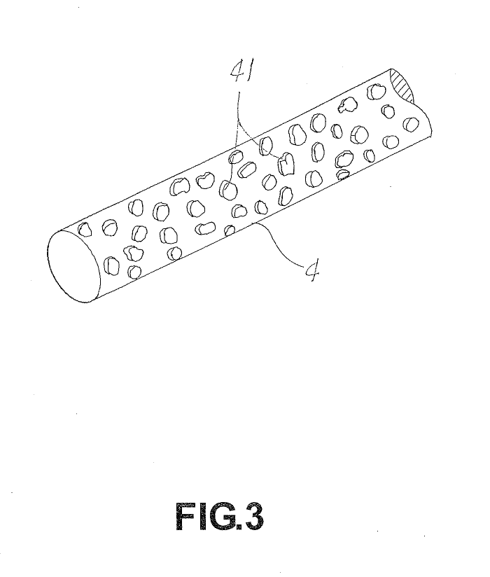

As shown in FIG. 3, the heatsink member 4 has a column shape and has a periphery provided with a plurality of irregular or rough surfaces 41 to increase the surface friction between the heatsink member 4 and the heatsink body 3 and to increase the surface area of the heatsink member 4 so as to enhance the heatsink effect of the heatsink device.

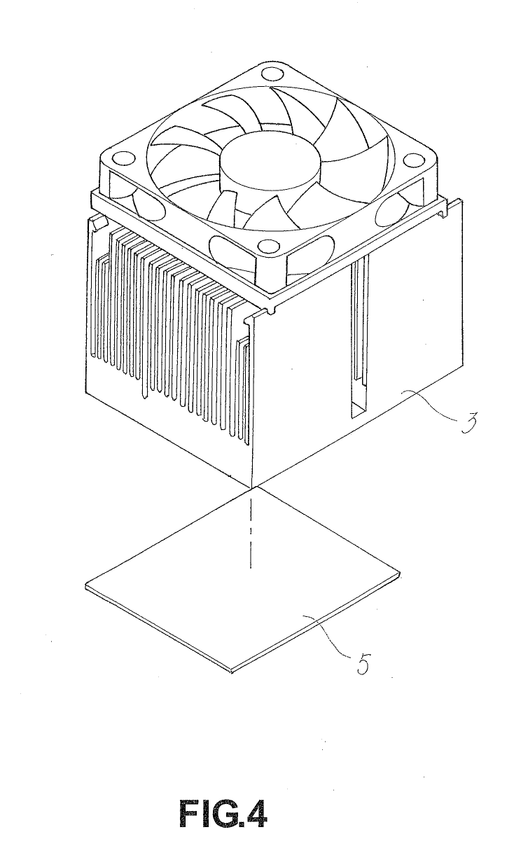

As shown in FIG. 4, the heatsink member is a flat plate 5 which is mounted on and combined with a bottom of the heatsink body 3 by a friction welding machine.

Accordingly, the heatsink body 3 and the heatsink member 4 are combined together by a friction welding machine without needing any solder, conducting paste, adhesive or bonding agent, so that the heatsink body 3 is directly combined with the heatsink member 4 without an obstruction located between the heatsink body 3 and the heatsink member 4 so as to enhance the heatsink effect of the heatsink device. In addition, the heatsink member 4 is attached to and combined with the heatsink body 3 at a high temperature so that the heatsink body 3 and the heatsink member 4 are combined solidly and stably without incurring a detachment. Further, the heatsink device has a better heatsink effect so as to enhance the lifetime of the electronic appliance. Further, the heatsink member 4 has a periphery provided with a plurality of irregular or rough surfaces 41 to increase the surface friction between the heatsink member 4 and the heatsink body 3 and to increase the surface area of the heatsink member 4 so as to enhance the heatsink effect of the heatsink device. Further, the heatsink member 4 is attached to and combined with the heatsink body 3 by a friction welding machine so that the heatsink body 3 and the heatsink member 4 are combined together easily and quickly.

Although the invention has been explained in relation to its preferred embodiment(s) as mentioned above, it is to be understood that many other possible modifications and variations can be made without departing from the scope of the present invention. It is, therefore, contemplated that the appended claim or claims will cover such modifications and variations that fall within the true scope of the invention.

1. A heatsink device, comprising:
a heatsink body;
a cooling fan mounted on a top of the heatsink body; and at least one heatsink member combined with the heatsink body;
wherein the heatsink body is combined with a circuit board;
the heatsink body has an upper end provided with a plurality of heatsink fins and a plurality of heatsink channels defined between the heatsink fins;
the improvement of the heatsink device, comprising:
the heatsink body is made of a metallic material;
the heatsink member is made of a metallic material different from that of the heatsink body;
the heatsink member is combined with the heatsink body in a friction welding manner without needing any solder.

2. The heatsink device of claim 1, wherein the heatsink member is made of a copper material.

3. The heatsink device of claim 2, wherein the heatsink member has a periphery provided with a plurality of irregular or rough surfaces.

4. The heatsink device of claim 2, wherein the heatsink member is an elongate copper rod or a flat plate.
